(19) United States
(12) Patent Application Publication
(10) Pub. No.: US 2025/0038118 A1
(43) Pub. Date: Jan. 30, 2025

(54) SEMICONDUCTOR CHIP HAVING AN INTERCONNECTION AREA AND SEMICONDUCTOR PACKAGE INCLUDING THE SAME

(71) Applicant: SAMSUNG ELECTRONICS CO., LTD., SUWON-SI (KR)

(72) Inventor: YOUNG-DEUK KIM, Suwon-si (KR)

(21) Appl. No.: 18/774,242

(22) Filed: Jul. 16, 2024

(30) Foreign Application Priority Data
Jul. 27, 2023 (KR) 10-2023-0098319

(51) Int. Cl. H01L 23/538; H01L 23/00; H01L 23/48; H01L 25/065; H10B 80/00

(52) U.S. Cl. CPC H01L 23/5386; H01L 23/481; H01L 24/08; H01L 24/16; H01L 25/0652; H10B 80/00; H01L 2224/08145; H01L 2224/16227; H01L 2225/06541

(57) ABSTRACT

A semiconductor package according to an embodiment includes a connection substrate, a first semiconductor chip, and a second semiconductor chip. The first semiconductor chip is disposed on the connection substrate and includes a first interconnection area facing the connection substrate. The second semiconductor chip is disposed on the connection substrate and includes a second interconnection area facing the connection substrate. The second semiconductor chip includes a first edge adjacent to the first semiconductor chip and a second edge opposite to the first edge in a first direction. A first distance between the second interconnection area and the first edge in the first direction is different from a second distance between the second interconnection area and the second edge in the first direction.

### CROSS-REFERENCE TO RELATED APPLICATION

This application claims priority to and the benefit of Korean Patent Application No. 10-2023-0098319 filed in the Korean Intellectual Property Office on Jul. 27, 2023, the entire contents of which are herein incorporated by reference.

### BACKGROUND

### (a) Technical Field

The present disclosure relates to a semiconductor chip having an interconnection area and a semiconductor package including the same, and more particularly, to a memory chip having an improved structure and a semiconductor package including the same.

### (b) Discussion of Related Art

Semiconductor devices may have a small size factor and may be configured to perform various functions, and thus are widely used in various electronic industries. Advancements in micro-fabrication technology and packaging technology have continued to reduce a size and increase the performance of the semiconductor devices.

A semiconductor package having a small size, multifunctionality, and high integration may include a plurality of semiconductor chips disposed on a substrate. The plurality of the semiconductor chips may be adjacent to each other in the semiconductor package, which may reduce a communication distance between chips and increase a speed of the semiconductor package. In the semiconductor package, heat generated by one semiconductor chip may be transferred to a peripheral semiconductor chip. When a temperature of the peripheral semiconductor chip is increased by the transfer of heat, an operational temperature of the peripheral semiconductor chip may be increased, and heat dissipation property and performance may be deteriorated.

### SUMMARY

Embodiments provide a semiconductor chip having an interconnection area having improved heat dissipation properties and performance, and a semiconductor package including the same.

A semiconductor package according to an embodiment includes a connection substrate, a first semiconductor chip, and a second semiconductor chip. The first semiconductor chip is disposed on the connection substrate and includes a first interconnection area facing the connection substrate. The second semiconductor chip is disposed on the connection substrate and includes a second interconnection area facing the connection substrate. The second semiconductor chip includes a first edge adjacent to the first semiconductor chip and a second edge opposite to the first edge in a first direction. A first distance between the second interconnection area and the first edge in the first direction is different from a second distance between the second interconnection area and the second edge in the first direction.

A memory chip according to an embodiment includes a plurality of semiconductor dies, and a plurality of connection pads at a surface of the plurality of semiconductor dies. The memory chip includes a first edge at a first side and a second edge at a second side opposite to the first side in a first direction. A first distance between the first edge and a first pad of the plurality of connection pads adjacent to the first edge in the first direction is smaller than a second distance between the second edge and a second pad of the plurality of connection pads adjacent to the second edge in the first direction.

A semiconductor package according to an embodiment includes an interposer, a logic chip, and a memory chip. The logic chip is disposed on the interposer and includes a first interconnection area configured to be connected to the interposer. The memory chip is disposed on the interposer and includes a second interconnection area configured to be connected to the interposer. The memory chip includes a first edge adjacent to the logic chip and a second edge opposite to the first edge in a first direction. A first distance between the second interconnection area and the first edge in the first direction is different from a second distance between the second interconnection area and the second edge in the first direction.

According to an embodiment, by adjusting a relative position between an interconnection area and a semiconductor chip, an interconnection interval between interconnection areas may be small and a separation distance between semiconductor chips may be increased. Accordingly, a heat dissipation property of the semiconductor package may be improved. Therefore, performance of the semiconductor package may be improved, for example, by reducing power for heat dissipation and reducing an operating temperature of the semiconductor package.

### BRIEF DESCRIPTION OF THE DRAWINGS

FIG. 1 is a plan view schematically illustrating a semiconductor package according to an embodiment.

FIG. 2 is a cross-sectional view of the semiconductor package shown in FIG. 1, taken along a I-I′ line.

FIG. 3 is a cross-sectional view illustrating a second semiconductor chip included in the semiconductor package shown in FIG. 1.

FIG. 4 illustrates plan views of a lower surface of a first semiconductor chip and a lower surface of the second semiconductor chip included in the semiconductor package shown in FIG. 1.

FIG. 5 is a plan view illustrating a connection substrate, the first semiconductor chip, and the second semiconductor chip included in the semiconductor package shown in FIG. 1.

FIG. 6 is a plan view schematically illustrating a semiconductor package according to an embodiment.

FIG. 7 is a plan view schematically illustrating a semiconductor package according to an embodiment.

### DETAILED DESCRIPTION

In the following detailed description, embodiments of the present disclosure will be described more fully hereinafter with reference to the accompanying drawings, in which embodiments of the disclosure are shown. The present disclosure may be implemented in various different forms and is not limited to embodiments provided herein.

Elements or components unrelated to the description may be omitted in order to clearly describe embodiments of the present disclosure, and the same or similar components are denoted by the same reference numerals throughout the present specification.

Further, since sizes and thicknesses of portions, regions, members, units, layers, films, etc. shown in the accompanying drawings may be arbitrarily shown for better understanding and ease of description, the present disclosure is not limited to the illustrated sizes and thicknesses. Thicknesses of some portions, regions, members, units, layers, films, etc. may be enlarged in the drawings in order to clearly describe embodiments of the present disclosure. In addition, in the drawings, thicknesses of portions, regions, members, units, layers, films, etc. may be exaggerated for convenience of explanation.

It will be understood that when a component such as a layer, film, region, or substrate is referred to as being “on” another component, it may be directly on other component or intervening components may also be present. In contrast, when a component is referred to as being “directly on” another component, there are no intervening components present. Further, when a component is referred to as being “on” or “above” a reference component, the component may be positioned above or below the reference component, and it does not necessarily mean that the component is located “on” or “above” the reference component in a direction opposite to gravity.

In addition, unless explicitly described to the contrary, the word “comprise” or “include”, and variations such as “comprises”, “comprising”, “includes”, “or including”, will be understood to imply the inclusion of stated components but not the exclusion of any other components.

Further, throughout the specification, a phrase “on a plane”, “in a plane”, “on a plan view”. or “in a plan view” may indicate a case where a portion is viewed from above or a top portion, and a phrase “on a cross-section” or “in a cross-section” may indicate a view of a cross-section along a vertical direction taken from a side.

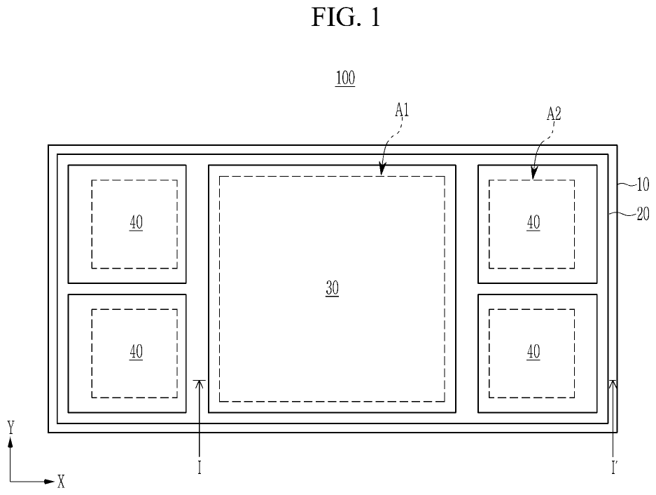

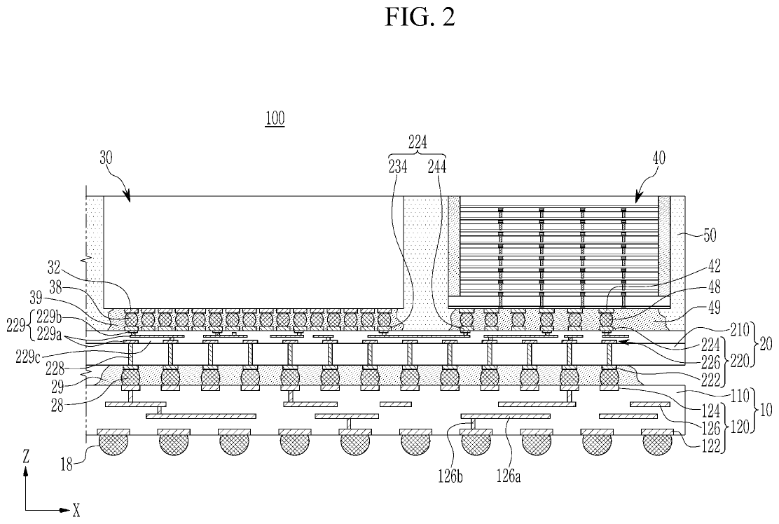

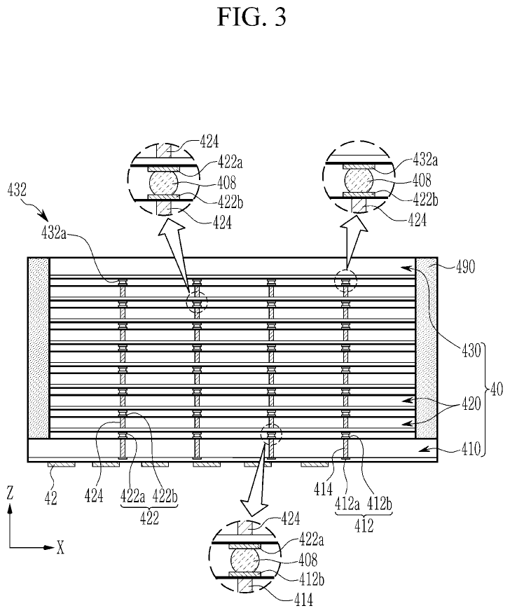

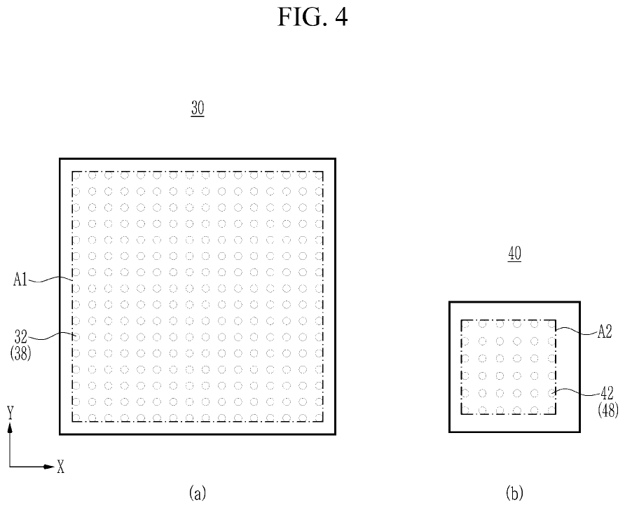

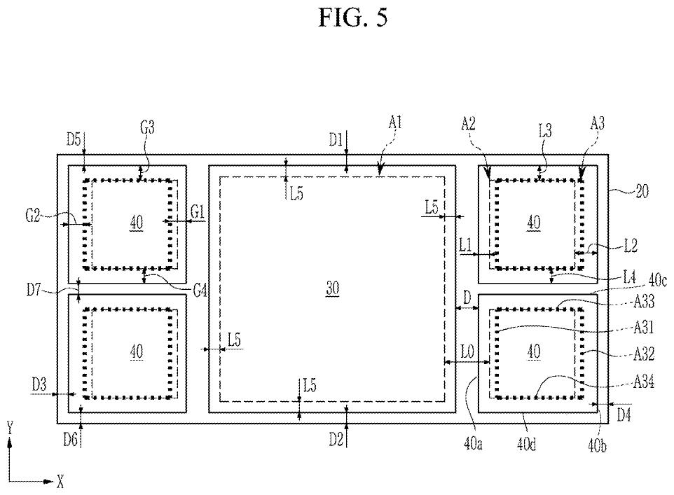

Hereinafter, a memory chip and a semiconductor package including the same according to an embodiment will be described in detail with reference to FIG. 1, FIG. 2, FIG. 3, FIG. 4, and FIG. 5,

FIG. 1 is a plan view schematically illustrating a semiconductor package according to an embodiment. FIG. 2 is a cross-sectional view of the semiconductor package shown in FIG. 1, taken along a I-I′ line. To provide concise illustrations and a clear understanding, a molding portion 50 is not illustrated in FIG. 1.

Referring to FIG. 1 and FIG. 2, a first semiconductor package 100 according to an embodiment includes a connection substrate 20, a first semiconductor chip 30 and a second semiconductor chip 40. The first semiconductor chip 30 and the second semiconductor chip 40 may be disposed on the connection substrate 20. The first semiconductor package 100 may be a 2.5D semiconductor package in which the first semiconductor chip 30 and the second semiconductor chip 40 may be positioned side-by-side and connected to each other by the connection substrate 20. As an example, the first semiconductor chip 30 may include a logic chip, and the second semiconductor chip 40 may include a memory chip. The first semiconductor package 100 may further include a package substrate 10, a molding portion 50, an external interconnection member 18, an interconnection member 28, an underfill layer 29, first interconnection members 38 and second interconnection members 48, and first underfill layers 39 and second underfill layers 49.

The connection substrate 20, the first semiconductor chip 30, and the second semiconductor chip 40 may be disposed on a first surface (e.g., an upper surface) of the package substrate 10, and the external interconnection member 18 may be disposed on a second surface (e.g., a lower surface) of the package substrate 10. The package substrate 10 may structurally support the connection substrate 20, the first semiconductor chip 30, and the second semiconductor chip 40. The package substrate 10 may be electrically connected to the connection substrate 20 through the interconnection member 28 on the upper surface of the package substrate 10, and may be electrically connected to an external circuit, an external device, or the like through the external interconnection member 18 on the lower surface of the package substrate 10.

In an embodiment, the package substrate 10 may include a plurality of wiring layers 120 and a substrate insulation layer 110. The plurality of wiring layers 120 may be positioned with the substrate insulation layer 110 interposed therebetween. The plurality of wiring layers 120 may include a lower substrate pad 122 at a lower surface of the substrate insulation layer 110 and an upper substrate pad 124 at an upper surface of the substrate insulation layer 110, and a substrate internal wiring 126 electrically connecting the lower substrate pad 122 and the upper substrate pad 124.

The lower substrate pad 122 may be a portion where the external interconnection member 18 is disposed for connection with an external circuit, an external device, or the like. The upper substrate pad 124 may be a portion where the interconnection member 28 is disposed for connection with the connection substrate 20. The substrate internal wiring 126 may include a wiring part 126a and a contact via 126b. The wiring part 126a may be extended on the substrate insulation layer 110 in a plan view, and the contact via 126b may penetrate the substrate insulation layer 110 to connect the wiring part 126a, the upper substrate pad 124, and/or the lower substrate pad 122.

In an embodiment, the package substrate 10 may be or include a printed circuit board (PCB). As an example, the substrate insulation layer 110 may include a resin material (e.g., a phenolic resin, an epoxy resin, or a polyimide), and the wiring layer 120 or the plurality of wiring layers 120 may include at least one of copper, aluminum, tungsten, nickel, gold, tin, manganese, cobalt, titanium, tantalum, ruthenium, or beryllium, or an alloy including the same. Embodiments are not limited thereto, and a structure, a shape, and a material of the package substrate 10 may be variously modified.

The external interconnection member 18 may have a land shape, a ball shape, or a pin shape. The external interconnection member 18 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the external interconnection member 18 may include tin or an alloy including tin (as an example, a Sn—Ag—Cu alloy). Embodiments are not limited thereto, and a shape, a material, or the like of the external interconnection member 18 may be variously modified.

In an embodiment, the first semiconductor chip 30 and the second semiconductor chip 40 may be mounted on the connection substrate 20, and the connection substrate 20 on which the first semiconductor chip 30 and the second semiconductor chip 40 are mounted may be disposed on the package substrate 10. More particularly, the interconnection member 28 for connection with the package substrate 10 may be disposed on a first surface (as an example, a lower surface) of the connection substrate 20, and the first semiconductor chip 30 and the second semiconductor chip 40 may be disposed on a second surface (as an example, an upper surface) of the connection substrate 20.

The connection substrate 20 may be a substrate having a finer pitch or a finer pattern than the package substrate 10. That is, the first semiconductor chip 30 and second semiconductor chip 40 and/or the package substrate 10 may be electrically connected with a fine pitch or a fine pattern using the connection substrate 20. For example, the connection substrate 20 may be or include an interposer or an interposer substrate.

In an embodiment, the connection substrate 20 may include a base layer 210 and a wiring portion 220. In this instance, the wiring portion 220 may include a lower pad 222 and an upper pad 224 at the lower and upper surfaces of the connection substrate 20, respectively, and an internal wiring 226 electrically connecting the lower pad 222 and the upper pad 224. The internal wiring 226 may include a wiring layer 229 including a wiring part 229a and a contact via 229b, and a through via (or a penetration via) 228.

In this instance, the wiring portion 220 of the connection substrate 20, i.e., the upper pad 224, the lower pad 222, and/or the internal wiring 226, may be connected to configure a certain circuit. The wiring portion 220 of the connection substrate 20 may perform various functions according to a design. For example, the wiring portion 220 of the connection substrate 20 may include a ground pattern, a power pattern, and a signal pattern. The signal pattern may be or include a pattern for transmitting various signals, e.g., data signals, or the like. The signal pattern may not transmit signals applied to the ground pattern or the power pattern, for example. The contact via 229b included in the wiring portion 220 may include, for example, a contact via for ground, a contact via for power, or a contact via for signal. The through via 228 included in the wiring portion 220 may include a through via for ground, a through via for power, a through via for signal, or the like.

Here, the base layer 210 may include, for example, a semiconductor material, an insulating material, a glass, or a ceramic. As an example, the base layer 210 may be or include a semiconductor substrate (e.g., silicon substrate) including a semiconductor material. As such, when the base layer 210 includes the silicon substrate, the first semiconductor chip 30 and the second semiconductor chip 40 include the same or similar materials, thereby having an excellent thermal stability. In some embodiments, the base layer 210 may be or include an insulation layer including an insulating material. For example, the base layer 210 may include a plurality of insulation layers. In a final structure, an interface between the plurality of insulation layers may be seen, or the interface between the plurality of insulation layers might not be seen and may be recognized as one insulation layer. In some embodiments, the base layer 210 may include an organic insulation layer (e.g., a photosensitive insulating material layer). In this instance, the wiring portion 220 may be or include a redistribution layer, and the connection substrate 20 may be or include a redistribution substrate or a redistribution portion.

The base layer 210 may be or include any of various materials other than the above-described materials, and a material, a structure, or the like of the connection substrate 20 may be variously modified.

In an embodiment, the lower pad 222 may be a portion where the interconnection member 28 is disposed for connection with the package substrate 10. The upper pad 224 may include a first pad 234 connected to the first semiconductor chip 30 and a second pad 244 connected to the second semiconductor chip 40.

More particularly, at the upper portion of the connection substrate 20, a plurality of first pads 234 may be disposed to correspond to the first semiconductor chip 30 (e.g., a first interconnection area A1), and a plurality of second pads 244 may be disposed to correspond to the second semiconductor chip 40 (e.g., a second interconnection area A1). For example, a plurality of first pads 234 may be spaced apart from each other at regular intervals in a first direction (in an X-axis direction in the drawing), and a plurality of first pads 234 may be spaced apart from each other at regular intervals in a second direction (in a Y-axis direction in the drawing) crossing the first direction. Similarly, a plurality of second pads 244 may be spaced apart from each other at regular intervals in the first direction (in the X-axis direction in the drawing), and a plurality of second pads 244 may be spaced apart from each other at regular intervals in the second direction (in the Y-axis direction in the drawing).

The internal wiring 226 may include the wiring layer 229 and the through via 228. The wiring layer 229 may include at least one of an upper wire layer positioned on an upper surface of the base layer 210 or a lower wiring layer positioned on a lower surface of the base layer 210 to configure a desired circuit. The wiring layer 229 may include the wiring part 229a and the contact via 229b. The wiring part 229a may be extended on an interlayer insulation layer 229c in a plan view, and the contact via 229b may penetrate the interlayer insulation layer 229c to connect the wiring part 229a, the lower pad 222, and/or the upper pad 224. The through via 228 may penetrate the base layer 210 to connect the lower pad 222 and the upper wiring layer, to connect the upper pad 224 and the lower wiring layer, or to connect the upper wiring layer and the lower wiring layer. For example, the through via 228 may be a through silicon via (TSV).

The internal wiring 226 may include a first inner wiring and a second inner wiring. The first inner wiring may electrically connect the upper pad 224 and the lower pad 222. The second inner wiring may electrically connect the first pad 234 and the second pad 244 to connect the first semiconductor chip 30 and the second semiconductor chip 40.

The base layer 210 may include any of various insulating materials that may electrically insulate wirings that should not be connected among the wiring portion 220. The wiring portion 220 of the connection substrate 20, i.e., the lower pad 222, the upper pad 224, and/or the internal wiring 226 (e.g., the wiring part 229a, the contact via 229b, and the through via 228) may include any of various conductive materials. At least two of the lower pad 222, the upper pad 224, the wiring part 229a, the contact via 229b, and/or the through via 228 may include or be formed of the same material, or may include different materials. The lower pad 222, the upper pad 224, the wiring part 229a, the contact via 229b, and/or the through via 228 may include or be formed of a single layer, or may include a plurality of layer. For example, the lower pad 222, the upper pad 224, the wiring part 229a, the contact via 229b, and/or the through via 228 may include at least one of copper, aluminum, tungsten, nickel, gold, tin, manganese, cobalt, titanium, tantalum, ruthenium, or beryllium, or an alloy including the same.

The interconnection member 28 may be disposed on the lower pad 222 at the lower surface of the connection substrate 20. The interconnection member 28 may be positioned between the lower pad 222 of the connection substrate 20 and the upper substrate pad 124 of the package substrate 10 to electrically connect the connection substrate 20 and the package substrate 10. An underfill layer 29 may be further included at a periphery of the interconnection member 28 between the connection substrate 20 and the package substrate 10.

The interconnection member 28 may have a land shape, a ball shape, or a pin shape. The interconnection member 28 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the interconnection member 28 may include tin or an alloy including tin (as an example, a Sn—Ag—Cu alloy). Embodiments are not limited thereto, and a shape, a material, or the like of the interconnection member 28 may be variously modified.

The underfill layer 29 may include a thermosetting resin such as an epoxy resin, a thermoplastic resin such as a polyimide, a resin including an inorganic filler and/or a glass fiber, or an epoxy molding compound (EMC). A material, a shape, or the like of the underfill layer 29 may be variously modified.

In the description, the package substrate 10 and the connection substrate 20 are separately provided and connected to each other by the interconnection member 28. It should be understood that embodiments are not limited thereto. In some embodiments, instead of the package substrate 10 and the connection substrate 20, a substrate incorporating the package substrate 10 and the connection substrate 20 may be used. For example, instead of the package substrate 10 and the connection substrate 20, a glass package substrate may be used. Other variations are possible.

FIG. 1 illustrates an example in which a size or an area of the package substrate 10 is larger than a size or an area of the connection substrate 20 in a plan view to have a structural stability. Embodiments are not limited thereto, and other variations are possible.

The first semiconductor chip 30 and the second semiconductor chip 40 may be disposed on the upper surface of the connection substrate 20, and the first semiconductor chip 30 and the second semiconductor chip 40 may be spaced apart from each other in a horizontal direction (as an example, a first direction or an X-axis direction). That is, the first semiconductor chip 30 and the second semiconductor chip 40 may be disposed side-by-side on the upper surface of the connection substrate 20.

In an embodiment, the first semiconductor chip 30 may include a central processing unit (CPU), a graphic processing unit (GPU), or an application specific integrated circuit (ASIC). Embodiments are not limited thereto, and the first semiconductor chip 30 may have any of various structures or schemes or perform any of various functions.

A first connection pad 32 in which the first interconnection member 38 is positioned for connection with the connection substrate 20 may be at a surface (as an example, a lower surface) of the first semiconductor chip 30 adjacent to the connection substrate 20.

In an embodiment, the second semiconductor chip 40 may be a stacked memory chip. This will be described in more detail with reference to FIG. 3, along with FIG. 2. FIG. 3 is a cross-sectional view illustrating the second semiconductor chip 40 included in the first semiconductor package 100 shown in FIG. 1.

Referring to FIG. 2 and FIG. 3, in an embodiment, the second semiconductor chip 40 may be or include a stacked memory chip formed by stacking and bonding a plurality of memory dies 420 and 430 and/or a buffer die 410. Each of the plurality of memory dies 420 and 430 and/or the buffer die 410 may be referred to as a semiconductor die.

In an embodiment, the second semiconductor chip 40 may be or include a set of memory chips including the plurality of memory dies 420 and 430 and/or the buffer die 410 capable of merging data with each other. The plurality of memory dies 420 and 430 may include an upper memory die 430 positioned at an upper portion, and one or plurality of the internal memory dies 420 positioned at a lower portion of the upper memory die 430. The buffer die 410 may be positioned at a lower portion of the plurality of memory dies 420 and 430.

In an embodiment, a thickness of the upper memory die 430 may be larger than a thickness of the internal memory die 420. The upper memory die 430 that does not include a penetration electrode 414 or 424 may have a relatively large thickness, and thus, a mechanical property of the second semiconductor chip 40 may be enhanced. It should be understood that embodiments are not limited thereto. In some embodiments, the thickness of the upper memory die 430 may be the same as or smaller than the thickness of the internal memory die 420.

The buffer die 410 may be at a lowermost portion of the second semiconductor chip 40. The buffer die 410 may be a temporary storage device, and the buffer die 410 may be referred to as a logic die, a base die, or the like. For example, when the plurality of memory dies 420 and 430 transmit data to or receive data from an external device (not shown), the data may be temporarily stored in the buffer die 410. Then, data loss that may occur when the plurality of memory dies 420 and 430 transmit data to or receive data from the external device may be suppressed or prevented. Particularly, data loss that may occur due to differences in a processing speed, a processing unit, and a usage time between the plurality of memory dies 420 and 430 and the external device may be suppressed or prevented.

In an embodiment, the buffer die 410 is provided. Embodiments are not limited thereto, and the second semiconductor chip 40 may have a buffer-less structure that does not include the buffer die 410. In the buffer-less structure, resistance, power consumption, and latency of the second semiconductor chip 40 may be reduced. Various other structures may be applied.

In an embodiment, the second semiconductor chip 40 may be or include a high bandwidth memory (HBM) chip in which the plurality of memory dies 420 and 430 and/or the buffer die 410 are stacked. The high bandwidth memory chip may include the plurality of memory dies 420 and 430 to have a plurality of memory channels. Accordingly, a relatively short delay time and a high bandwidth simultaneously may be simultaneously implemented. In addition, an area of the second semiconductor chip 40 may be reduced by stacking the plurality of memory dies 420 and 430.

In an embodiment, the plurality of memory dies 420 and 430 and/or the buffer die 410 may include a volatile memory or a non-volatile memory. For example, the plurality of memory dies 420 and 430 and/or the buffer die 410 may be or include a dynamic random access memory (DRAM) as a volatile memory. In some embodiments, the plurality of memory dies 420 and 430 and/or the buffer die 410 may be or include a static random access memory (SRAM), a thyristor random access memory (TRAM), a zero-capacitor random access memory (ZRAM), or the like as a volatile memory. In some embodiments, the plurality of memory dies 420 and 430 and/or the buffer die 410 may be or include a flash memory, a resistive random access memory (RRAM), or the like as a non-volatile memory.

The plurality of memory dies 420 and 430 and/or the buffer die 410 may include a semiconductor substrate, a memory device portion on at least one surface of the semiconductor substrate, and a wiring portion 412, 422, and/or 432 for connection between the plurality of memory dies 420 and 430 and/or the buffer die 410, respectively. In this instance, the wiring portion 412 may include first bonding pads 412a and second bonding pads 412b, the wiring portion 422 may include first bonding pads 422a and second bonding pads 422b, and the wiring portion 432 may include a bonding pad 432a. The internal memory die 420 and/or the buffer die 410 may include the penetration electrodes 414 and 424 penetrating the semiconductor substrate. The internal memory die 420 and/or the buffer die 410 may be connected to each other through the penetration electrodes 414 and 424.

More particularly, the buffer die 410 may include a wiring portion 412 and a penetration electrode 414. The wiring portion 412 may include first bonding pads 412a at a lower surface of the buffer die 410 and second bonding pads 412b at an upper surface of the buffer die 410. The internal memory die 420 may include a wiring portion 422 and a penetration electrode 424. The wiring portion 422 may include first bonding pads 422a at a lower surface of the internal memory die 420 and second bonding pads 422b at an upper surface of the internal memory die 420. The upper memory die 430 may include a wiring portion 432. The wiring portion 432 may include a first bonding pad 432a at a lower surface of the upper memory die 430 facing the internal memory die 420.

In this case, the penetration electrodes 414 and 424 may penetrate the buffer die 410 (e.g., the semiconductor substrate included in the buffer die 410) or the internal memory die 420 (e.g., the semiconductor substrate included in the internal memory die 420), respectively. For example, the penetration electrode 414 or 424 may be or include a through silicon via (TSV). The penetration electrode 414 of the buffer die 410 and the penetration electrode 424 of the internal memory die 420 may be positioned at the same position in a plan view. For example, the penetration electrode 414 of the buffer die 410 and the penetration electrode 424 of the internal memory die 420 may be vertically stacked in a vertical direction (e.g., the Z-axis direction). Then, a connection path may be reduced and thus a problem such as signal loss may be reduced. It should be understood that embodiments are not limited thereto.

In the drawings, an example in which the plurality of memory dies 420 and 430 and/or the buffer die 410 are connected by an interconnection member 408 is illustrated. In this instance, the interconnection member 408 may have a land shape, a ball shape, or a pin shape. The interconnection member 408 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the interconnection member 408 may include tin or an alloy including tin. Embodiments are not limited thereto, and a shape, a material, or the like of the interconnection member 408 may be variously modified.

More particularly, the second bonding pad 412b of the buffer die 410 and the first bonding pad 422b of the internal memory die 420 may be connected by the interconnection member 408. The second bonding pad 422b of one internal memory die 420 and the first bonding pad 422a of another internal memory die 420 on the one internal memory die 420 may be connected by the interconnection member 408. The second bonding pad 422b of the internal memory die 420 and the first bonding pad 432a of the upper memory die 430 on the internal memory die 420 may be connected by the interconnection member 408.

Embodiments are not limited thereto, and the plurality of memory dies 420 and 430 and/or the buffer die 410 may be connected to each other by a hybrid bonding or direct bonding. In this instance, a first insulation layer may be positioned at a periphery of each of the first bonding pads 422a and 432a, and a second insulation layer may be positioned at a periphery of each of the second bonding pads 412b and 422b. In this instance, the first bonding pads 422a and 432a and the second bonding pads 412b and 422b may be directly connected and bonded to each other to form a metal bonding. The first insulation layer and the second insulation layer may be directly connected and bonded to each other to form an insulation-layer bonding. By bonding the plurality of memory dies 420 and 430 and/or the buffer die 410 through the hybrid bonding, the interconnection member 408 may be not used and a bonding pitch may be reduced. The plurality of memory dies 420 and 430 and/or the buffer die 410 may be bonded to each other in various other ways.

A side molding portion 490 may be disposed on a side surface of the second semiconductor chip 40. In the drawings, an example in which the side molding portion 490 is on the side surface of the plurality of memory dies 420 and 430 is illustrated. Embodiments are not limited thereto, and the side molding portion 490 may also be disposed on a side surface of the buffer die 410. The side molding portion 490 may include, for example, a thermosetting resin such as an epoxy resin, a thermoplastic resin such as a polyimide, a resin including an inorganic filler and/or a glass fiber, or an epoxy molding compound (EMC). A material, a shape, or the like of the side molding portion 490 may be variously modified.

In the drawings, an example in which a size or an area of the buffer die 410 is larger than a size or an area of the plurality of memory dies 420 and 430 in a plan view to have a structural stability is illustrated. It should be understood that embodiments are not limited thereto. In some embodiments, a size or an area of the buffer die 410 may be the same as or smaller than a size or an area of the plurality of memory dies 420 and 430 in a plan view. In the drawings, an example in which the plurality of memory dies 420 and 430 include eight memory dies is illustrated. In some embodiments, the plurality of memory dies 420 and 430 may include four, twelve, or sixteen memory dies. Embodiments are not limited thereto, and a number of the plurality of memory dies 420 and 430 may be different from the described above.

A second connection pad 42 in which the second interconnection member 48 is positioned for connection with the connection substrate 20 may be at a surface (as an example, a lower surface) of the second semiconductor chip 40. For example, the second connection pad 42 may be disposed on a surface (as an example, a lower surface) of the plurality of memory dies 420 and 430 and/or the buffer die 410. As an example, the second connection pad 42 may be electrically connected to the first bonding pad 412a at the lower surface of the buffer die 410 through a wiring portion of the buffer die 410.

Referring to FIG. 1 and FIG. 2, in an embodiment, the first interconnection member 38 may be disposed between the first connection pad 32 of the first semiconductor chip 30 and the upper pad 224 (more particularly, the first pad 234) of the connection substrate 20 to electrically connect the first semiconductor chip 30 and the connection substrate 20. The second interconnection member 48 may be disposed between the second connection pad 42 of the second semiconductor chip 40 and the upper pad 224 (more particularly, the second pad 244) of the connection substrate 20 to electrically connect the second semiconductor chip 40 and the connection substrate 20.

The first interconnection member 38 or the second interconnection member 48 may have a land shape, a ball shape, or a pin shape. The first interconnection member 38 or the second interconnection member 48 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the first interconnection member 38 or the second interconnection member 48 may include tin or an alloy including tin (as an example, a Sn—Ag—Cu alloy). Embodiments are not limited thereto this, and a shape, a material, or the like of the first interconnection member 38 or the second interconnection member 48 may be variously modified.

A first underfill layer 39 may be further included at a periphery of the first interconnection member 38 between the first semiconductor chip 30 and the connection substrate 20. A second underfill layer 49 may be further included at a periphery of the second interconnection member 48 between the second semiconductor chip 40 and the connection substrate 20.

The first underfill layer 39 or the second underfill layer 49 may include a thermosetting resin such as an epoxy resin, a thermoplastic resin such as a polyimide, a resin including an inorganic filler and/or a glass fiber, an epoxy molding compound, or the like. In an embodiment, as an example, the first underfill layer 39 is positioned between the first semiconductor chip 30 and the connection substrate 20, and the second underfill layer 49 is between the second semiconductor chip 40 and the connection substrate 20. It should be understood that embodiments are not limited thereto. In some embodiments, the first and second semiconductor chips 30 and 40 and the connection substrate 20 may be connected to each other by one molding portion between the first and second semiconductor chips 30 and 40 and the connection substrate 20. In an embodiment, a material, a shape, or the like of the first underfill layer 39 and/or the second underfill layer 49 may be variously modified.

The molding portion 50 surrounding the first semiconductor chip 30 and the second semiconductor chip 40 on the connection substrate 20 may be further included. For example, the molding portion 50 may cover an entire portion of a side surface of at least the first and second semiconductor chips 30 and 40 and entirely fill a space between the first semiconductor chip 30 and the second semiconductor chip 40. The molding portion 50 may include a thermosetting resin such as an epoxy resin, a thermoplastic resin such as a polyimide, a resin including an inorganic filler and/or a glass fiber, or an epoxy molding compound. Embodiments are not limited thereto, and a shape, a material, or the like of the molding portion 50 may be variously modified.

In FIG. 1, an example in which an upper surface of the first semiconductor chip 30 and an upper surface of the second semiconductor chip 40 are on the same plane and the molding portion 50 is disposed on the side surfaces of the first and second semiconductor chips 30 and 40 is illustrated. It should be understood that embodiments are not limited thereto. For example, at least of a part of the molding portion 50 may be at an upper portion of at least one of the first semiconductor chips 30 or second semiconductor chips 40. In some embodiments, the upper surface of the first semiconductor chip 30 and the upper surface of the second semiconductor chip 40 may be disposed on different planes. Other variations are possible.

In an embodiment, by adjusting an arrangement of the first interconnection area A1 and the first semiconductor chip 30 and/or an arrangement of the second interconnection area A2 and the second semiconductor chip 40, a separation distance D (refer to FIG. 5) between the first semiconductor chip 30 and the second semiconductor chip 40 may be adjusted. Here, the separation distance D may refer to a shortest distance between the first semiconductor chip 30 and the second semiconductor chip 40. In the drawings, the first semiconductor chip 30 and the second semiconductor chip 40 may be adjacent to each other in a first direction (an X-axis direction in the drawing), and the separation distance D may refer to a distance between the first semiconductor chip 30 and the second semiconductor chip 40 in the first direction.

Referring to FIG. 4 and FIG. 5, along with FIG. 1 to FIG. 3, the arrangement of the first interconnection area A1 and the first semiconductor chip 30, the arrangement of the second interconnection area A2 and the second semiconductor chip 40, the separation distance D between the first semiconductor chip 30 and the second semiconductor chip 40, and other aspects will be described in more detail.

FIG. 4 illustrates plan views of the lower surface of the first semiconductor chip 30 and the lower surface of the second semiconductor chip 40 included in the first semiconductor package 100 shown in FIG. 1. FIG. 4 illustrates a relationship between the first interconnection area A1 (e.g., the first connection pad 32 and/or the first interconnection member 38) and the first semiconductor chip 30, and a relationship between the second interconnection area A2 (e.g., the second connection pad 42 and/or the second interconnection member 48) and the second semiconductor chip 40. In FIG. 4, the first connection pads 32 and the second connection pads 42, and/or the first interconnection members 38 and the second interconnection members 48, the first interconnection areas A1 and the second interconnection areas A2, and the first second semiconductor chips 30 and the second semiconductor chips 40 are mainly illustrated.

Referring to FIG. 4, a plurality of first connection pads 32 and/or a plurality of first interconnection members 38 may be in the first interconnection area A1, and a plurality of second connection pads 42 and/or a plurality of second interconnection members 48 may be in the second interconnection area A2.

The first interconnection area A1 may be an area including the plurality of first connection pads 32 or an area including the plurality of first interconnection members 38 in a plan view. The first interconnection area A1 may encompass the plurality of first connection pads 32 and the plurality of first interconnection members 38 in a plan view. The second interconnection area A2 may be an area including the plurality of second connection pads 42 or an area including the plurality of second interconnection members 48 in a plan view. The second interconnection area A2 may be an area surrounding the plurality of second connection pads 42 and the plurality of second interconnection members 48 in a plan view.

According to an embodiment, in the first interconnection area A1, a plurality of first connection pads 32 may be spaced apart from each other at regular intervals in a first direction (in the X-axis direction in the drawing), and a plurality of first connection pads 32 may be spaced apart from each other at regular intervals in a second direction (in the Y-axis direction in the drawing). In the first interconnection area A1, a plurality of first interconnection members 38 may be spaced apart from each other at regular intervals in the first direction, and a plurality of first interconnection members 38 may be spaced apart from each other at regular intervals in the second direction. In the first interconnection area A1, the plurality of first connection pads 32 and the plurality of first interconnection members 38 may correspond to each other. For example, the plurality of first connection pads 32 and the plurality of first interconnection members 38 may correspond to each other in a one-to-one arrangement. In the first interconnection area A1, the plurality of first pads 234 of the connection substrate 20 and the plurality of first interconnection members 38 may correspond to each other. For example, the plurality of first pads 234 of the connection substrate 20 and the plurality of first interconnection members 38 may correspond to each other in a one-to-one arrangement.

According to an embodiment, in the second interconnection area A2, a plurality of second connection pads 42 may be spaced apart from each other at regular intervals in the first direction (in the X-axis direction in the drawing), and a plurality of second connection pads 42 may be spaced apart from each other at regular intervals in the second direction (in the Y-axis direction in the drawing). In the second interconnection area A2, a plurality of second interconnection members 48 may be spaced apart from each other at regular intervals in the first direction, and a plurality of second interconnection members 48 may be spaced apart from each other at regular intervals in the second direction. In the second interconnection area A2, the plurality of second connection pads 42 and the plurality of second interconnection members 48 may correspond to each other. For example, the plurality of second connection pads 42 and the plurality of second interconnection members 48 may correspond to each other in a one-to-one arrangement. In the second interconnection area A2, the plurality of second pads 244 of the connection substrate 20 and the plurality of second interconnection members 48 may correspond to each other. For example, the plurality of second pads 244 of the connection substrate 20 and the plurality of second interconnection members 48 may correspond to each other in a one-to-one arrangement.

Embodiments are not limited thereto, and the arrangement of the first interconnection members 38 and the second interconnection members 48, the first connection pads 32 and the second connection pads 42, or the like may be variously modified.

In FIG. 4, it is illustrated that a size, an interval, and a shape of the first connection pads 32 or the first interconnection members 38 are the same as a size, an interval, and a shape of the second connection pads 42 or the second interconnection members 48, respectively. Embodiments are not limited thereto, and a size, an interval, and a shape of the first and second connection pads 32 and 42 or the first and second interconnection members 38 and 48 may be variously modified.

FIG. 5 is a plan view illustrating the connection substrate 20, the first semiconductor chip 30, and the second semiconductor chip 40 included in the first semiconductor package 100 shown in FIG. 1.

Referring to FIG. 5, in an embodiment, a first distance L1 between the second interconnection area A2 and a first edge 40a of the second semiconductor chip 40 may be different from a second distance L2 between the second interconnection area A2 and a second edge 40b of the second semiconductor chip 40.

Here, in the first direction (the X-axis direction in the drawing) in which the first semiconductor chip 30 and the second semiconductor chip 40 may be positioned together, the first edge 40a of the second semiconductor chip 40 may be an edge of the second semiconductor chip 40 adjacent to the first semiconductor chip 30. In the first direction, the second edge 40b of the second semiconductor chip 40 may be an edge far from the first semiconductor chip 30 or an edge opposite to the first edge 40a. The first distance L1 may be a shortest distance between the second interconnection area A2 and the first edge 40a or a distance between the second interconnection area A2 and the first edge 40a in the first direction. The second distance L2 may be a shortest distance between the second interconnection area A2 and the second edge 40b or a distance between the second interconnection area A2 and the second edge 40b in the first direction. In an embodiment, the first distance L1 may be a distance between the first edge 40a and a first pad of the plurality of the second connection pads 32 adjacent to the first edge 40a in the first direction. The second distance L2 may be a distance between the second edge 40b and a second pad of the plurality of the second connection pads adjacent to the second edge 40b in the first direction.

In an embodiment, the separation distance D between the first semiconductor chip 30 and the second semiconductor chip 40 may be adjusted by adjusting the first distance L1 and the second distance L2.

In this instance, the first distance L1 may be smaller than the second distance L2. As an example, a ratio (L2/L1) of the second direction L2 to the first distance L1 may be between about 1.5 to 10 (e.g., 2 to 6). If the ratio (L2/L1) is less than about 1.5 (for example, 2), the reduction of the separation distance D between the first semiconductor chip 30 and the second semiconductor chip 40 might not be sufficient. If the ratio (L2/L1) is larger than about 10 (for example, 6), the first distance L1 may be reduced, and the stability may be deteriorated. It should be understood that embodiments are not limited thereto. In some embodiments, the ratio (L2/L1) may be less about 1.5 or may be larger than about 10.

When the first distance L1 is smaller than the second distance L2 as in the above, the second interconnection area A2 and the second semiconductor chip 40 may have an asymmetrical structure in the first direction. In the specification, the phrase of “an asymmetrical structure in one direction” may include a case that a distance between edges at one side in the one direction is different from a distance between edges at the other side in the one direction. In an embodiment, based on the second interconnection area A2, the second semiconductor chip 40 may be shifted in a direction away from the first semiconductor chip 30 in the first direction.

More particularly, the plurality of second connection pads 42 and the second semiconductor chip 40 may have an asymmetrical structure in the first direction. Alternatively, based on the plurality of second connection pads 42, the second semiconductor chip 40 may be shifted in the direction away from the first semiconductor chip 30 in the first direction. The plurality of second interconnection members 48 and the second semiconductor chip 40 may have an asymmetrical structure in the first direction. Alternatively, based on the plurality of second interconnection members 48, the second semiconductor chip 40 may be shifted in the direction away from the first semiconductor chip 30 in the first direction.

Alternatively, based on the second semiconductor chip 40, the second interconnection area A2 may be shifted in a direction approaching the first semiconductor chip 30 in the first direction. For example, based on the second semiconductor chip 40, the plurality of second connection pads 42 or the plurality of second interconnection members 48 may be shifted in the direction approaching the first semiconductor chip 30 in the first direction.

According to this, an interconnection interval L0 between the first interconnection area A1 and the second interconnection area A2 may be small, and the separation distance D between the first semiconductor chip 30 and the second semiconductor chip 40 may be increased. Here, the interconnection interval L0 may be a shortest distance between the first interconnection area A1 and the second interconnection area A2 or a distance between the first interconnection area A1 and the second interconnection area A2 in the first direction. The interconnection interval L0 between the first interconnection area A1 and the second interconnection area A2 may be a communication distance (e.g., a minimum communication distance) for communicating the first semiconductor chip 30 and the second semiconductor chip 40 each other. In an example in which the communication distance is small, a signal loss may be reduced, and a performance of the first semiconductor package 100 may be improved.

In an embodiment, a third distance L3 between the second interconnection area A2 and a third edge of the second semiconductor chip 40 may be substantially the same as a fourth distance L4 between the second interconnection area A2 and a fourth edge of the second semiconductor chip 40. In the specification, the phrase that two distances, two gaps, or two intervals are substantially the same may include a case in which they are the same and a case in which there is a difference within the process error (e.g., a difference within 10%).

Here, the third edge 40c of the second semiconductor chip 40 may be an edge intersecting (e.g., perpendicular to) the first and second edge 40a and 40b. The fourth edge 40d of the second semiconductor chip 40 may be an edge intersecting (e.g., perpendicular to) the first and second edge 40a and 40b and opposite to the third edge 40c. The third distance L3 may be a shortest distance between the second interconnection area A2 and the third edge 40c or a distance between the second interconnection area A2 and the third edge 40c in the second direction. The fourth distance L4 may be a shortest distance between the second interconnection area A2 and the fourth edge 40d or a distance between the second interconnection area A2 and the fourth edge 40d in the second direction. In an embodiment, the third distance L3 may be a distance between the third edge 40c and a third pad of the plurality of the first connection pad 32 adjacent to the third edge 40a in the second direction. The second distance L2 may be a distance between the fourth edge 40d and a fourth pad of the plurality of the first connection pad 32 adjacent to the fourth edge 40d in the second direction.

Accordingly, the second interconnection area A2 and the second semiconductor chip 40 may have a symmetrical structure. In the specification, the phrase of “a symmetrical structure in one direction” may include a case that a distance between edges at a first side in a given direction is substantially the same as a distance between edges at a second side in the given direction, wherein the first side and the second side are opposite each other. More particularly, the plurality of second connection pads 42 and the second semiconductor chip 40 may have a symmetrical structure in the second direction. The plurality of second interconnection members 48 and the second semiconductor chip 40 may have a symmetrical structure in the second direction.

The third distance L3 and the fourth distance L4 does not affect the separation distance D between the first semiconductor chip 30 and the second semiconductor chip 40. In an embodiment, the third distance L3 and the fourth distance L4 may be substantially the same to have a symmetrical structure, thereby improving a structural stability.

In an embodiment, the third distance L3 and/or the fourth distance L4 may be larger than the first distance L1 and may be smaller than the second distance L2. The third distance L3 and/or fourth distance L4 may be larger than the first distance L1 to enhance a stability, and may be smaller than the second distance L2 to reduce an unnecessary area. It should be understood that embodiments are not limited thereto. The third distance L3 and/or fourth distance L4 may be the same or smaller than the first distance L1, and/or may be the same or larger than the second distance L2.

In an embodiment, in a plan view, the second underfill layer 49 and the second semiconductor chip 40 may have a symmetrical structure in the first direction and the second direction. For example, in the first direction, a distance between an edge of the second underfill layer 49 and an edge of the second semiconductor chip 40 at one side may be substantially the same as a distance between an edge of the second underfill layer 49 and an edge of the second semiconductor chip 40 at the other side. For example, in the second direction, a distance between an edge of the second underfill layer 49 and an edge of the second semiconductor chip 40 at one side may be substantially the same as a distance between an edge of the second underfill layer 49 and an edge of the second semiconductor chip 40 at another side.

In an embodiment, in the first direction, the second underfill layer 49 and the second interconnection area A2 may have an asymmetrical structure. For example, in the first direction, a distance between an edge of the second interconnection area A2 and an edge of the second underfill layer 49 adjacent to the first edge 40a may be smaller than a distance between an edge of the second interconnection area A2 and an edge of the second underfill layer 49 adjacent to the second edge 40b. More particularly, in the first direction, a distance between an edge of the first pad and an edge of the second underfill layer 49 adjacent to the first edge 40a may be smaller than a distance between an edge of the second pad and an edge of the second underfill layer 49 adjacent to the second edge 40b. In an embodiment, in the first direction, a distance between an edge of the second interconnection member 48 and an edge of the second underfill layer 49 adjacent to the first edge 40a may be smaller than a distance between an edge of the second interconnection member 48 and an edge of the second underfill layer 49 adjacent to the second edge 40b.

In an embodiment, in the second direction, the second underfill layer 49 and the second interconnection area A2 may have a symmetrical structure. For example, in the second direction, a distance between an edge of the second interconnection area A2 and an edge of the second underfill layer 49 adjacent to the third edge 40c may be substantially the same as a distance between an edge of the second interconnection area A2 and an edge of the second underfill layer 49 adjacent to the fourth edge 40d. More particularly, in the second direction, a distance between an edge of the third pad and an edge of the second underfill layer 49 adjacent to the third edge 40c may be substantially the same as a distance between an edge of the fourth pad and an edge of the second underfill layer 49 adjacent to the fourth edge 40d. In an embodiment, in the second direction, a distance between an edge of the second interconnection member 48 and an edge of the second underfill layer 49 adjacent to the third edge 40c may be substantially the same as a distance between an edge of the second interconnection member 48 and an edge of the second underfill layer 49 adjacent to the fourth edge 40d.

In an embodiment, a plurality of penetration electrodes 414 and 424 may be spaced apart from each other at regular intervals in the first direction (in the X-axis direction in the drawing), respectively, and a plurality of penetration electrodes 414 and 424 may be spaced apart from each other at regular intervals in the second direction (in the Y-axis direction in the drawing), respectively. An area where the plurality of penetration electrodes 414 and 424 may be referred to as a penetration interconnection area A3. The penetration connection area A3 may be an area formed by connecting outermost parts of the plurality of penetration electrodes 414 and 424 with straight lines in a plan view.

As an example, in the first direction, a first gap G1 between a first edge A31 of the penetration connection area A3 and the first edge 40a of the second semiconductor chip 40 may be substantially the same as a second gap G2 between a second edge A32 of the penetration connection area A3 and the second edge 40b of the second semiconductor chip 40. In the second direction, a third gap G3 between a third edge A33 of the penetration connection area A3 and the third edge 40c of the second semiconductor chip 40 may be substantially the same as a fourth gap G4 between a fourth edge A34 of the penetration connection area A3 and the fourth edge 40d of the second semiconductor chip 40. In an embodiment, in each of the first direction and the second direction, the penetration connection area A3 and the second semiconductor chip 40 may have a symmetrical structure. In this instance, the first gap G1 and the second gap G2 may be substantially the same as or different from the third gap G3 and the fourth gap G4.

In an embodiment, in the first direction, the second interconnection area A2 and the penetration connection area A3 may have an asymmetrical structure. In an embodiment, relative to a position of the second interconnection area A2, the penetration connection area A3 may be shifted in the direction away from the first semiconductor chip 30 in the first direction.

More particularly, in the first direction, the plurality of second connection pads 42 and the penetration connection area A3 may have an asymmetrical structure. In an embodiment, relative to a position of the plurality of second connection pads 42, the penetration connection area A3 may be shifted in the direction away from the first semiconductor chip 30 in the first direction. In the first direction, the plurality of second interconnection members 48 and the penetration connection area A3 may have an asymmetrical structure. In an embodiment, relative to a position of the plurality of second interconnection members 48, the penetration connection area A3 may be shifted in the direction away from the first semiconductor chip 30 in the first direction.

Relative to a position of the penetration connection area A3, the second interconnection area A2 may be shifted in a direction approaching the first semiconductor chip 30 in the first direction. For example, relative to a position of the penetration connection area A3, the plurality of second connection pads 42 or the plurality of second interconnection members 48 may be shifted in a direction approaching the first semiconductor chip 30 in the first direction.

In an embodiment, in the second direction, the second interconnection area A2 and the penetration connection area A3 may have a symmetrical structure. More particularly, in the second direction, the plurality of second connection pads 42 and the penetration connection area A3 may have a symmetrical structure. In the second direction, the plurality of second interconnection member 48 and the penetration connection area A3 may have a symmetrical structure.

In this instance, the first distance L1 may be smaller than at least one of the first to fourth gaps G1, G2, G3, or G4. The second distance L2, the third distance L3, and/or the fourth distance L4 may be substantially the same, smaller than, or larger than at least one of first to fourth gaps G1, G2, G3, or G4.

In the drawing, it is illustrated that a size or an area of the penetration connection area A3 is substantially the same as a size or an area of the second interconnection area A2 and the third and fourth gaps G3 and G4 are substantially the same as the third and fourth distances L3 and L4, respectively. It should be understood that embodiments are not limited thereto. In some embodiments, the size or the area of the penetration connection area A3 may be larger than or smaller than the size or the area of the second interconnection area A2. In an embodiment, at least one of the third gap G3 or fourth gap G4 may be larger than at least one of the third distance L3 or the fourth distance L4 or may be smaller than at least one of the third distance L3 or the fourth distance L4.

In an embodiment, the first semiconductor chip 30 and the first interconnection area A1 may have a symmetrical structure in each of the first direction and the second direction. For example, each of distances between both edges of the first semiconductor chip 30 and both edges of the first interconnection area A1 at both sides in the second direction may be a fifth distance L5, and each of distances between both edges of the first semiconductor chip 30 and both edges of the first interconnection area A1 at both sides in the second direction may be the fifth distance L5. The fifth distance L5 may be a shortest distance between the edge of the first interconnection area A1 and the edge of the second semiconductor chip 40.

More particularly, in the first direction, the plurality of the first connection pads 32 and the first semiconductor chip 30 may have a symmetrical structure. In the first direction, the plurality of the first interconnection members 38 and the first semiconductor chip 30 may have a symmetrical structure. In the second direction, an area where the plurality of the first connection pads 32 are positioned and the first semiconductor chip 30 may have a symmetrical structure. In the second direction, the plurality of the first interconnection members 38 and the first semiconductor chip 30 may have a symmetrical structure.

For example, the fifth distance L5 may be the same or larger than the first distance L1. The fifth distance L5 may be smaller than each of the second distance L2, the third distance L3, the fourth distance L4. An area of the first interconnection area A1 may be determined according to a size of the first semiconductor chip 30 and the fifth distance L5. Embodiments are not limited thereto, and the fifth distance L5 may be smaller than the first distance L1, or may be the same as or larger than at least one of the second, third, or fourth distance L2, L3, or L4.

In an embodiment, as an example, the distances between edges of the first semiconductor chip 30 and edges of the first interconnection area A1 may be substantially the same as the fifth distance L5. The area of the first interconnection area A1 may be determined according to a size of the first semiconductor chip 30 and the fifth distance L5. It should be understood that embodiments are not limited thereto. For example, the distance between the edge of the first semiconductor chip 30 and the edge of the first interconnection area A1 in the first direction may be different from the distance between the edge of the first semiconductor chip 30 and the edge of the first interconnection area A1 in the second direction. In this instance, the first interconnection area A1 and the first semiconductor chip 30 may have a symmetrical structure in the first direction, and the first interconnection area A1 and the first semiconductor chip 30 may have a symmetrical structure in the second direction.

The first semiconductor chip 30 may include a relatively large number of the first connection pads 32 or the first interconnection members 38, and the fifth distance L5 between the first interconnection area A1 and the edge of the first semiconductor chip 30 may be relatively small. The second semiconductor chip 40 may include a relatively small number of the second connection pads 42 or the second interconnection members 48, and the distance between the second interconnection area A2 and the edge of the second semiconductor chip 40 may be relatively large. That is, a relative position between the second interconnection area A2 and the second semiconductor chip 40 may be adjusted, and a relative position between the first interconnection area A1 and the first semiconductor chip 30 may be maintained, for example, having a symmetric structure. For example, the first semiconductor chip 30 and the first interconnection area A1 have the symmetrical structure, and the second semiconductor chip 40 and the second interconnection area A2 form the asymmetrical structure in the first direction. It should be understood that embodiments are not limited thereto. For example, by adjusting the relative position between the first interconnection area A1 and the first semiconductor chip 30, the first interconnection area A1 and the first semiconductor chip 30 may form an asymmetrical structure in the first direction. Various other modifications are possible.

Referring to FIG. 5, in a plan view, a center portion of the first semiconductor chip 30 and a center portion of the first interconnection area A1 may be aligned, and a center portion of the second semiconductor chip 40 and a center portion of the second interconnection area A2 may be offset. For example, the center portion of the second semiconductor chip 40 may be offset from the center portion of the second interconnection area A2 and away from the first semiconductor chip 30. Further, by adjusting the relative positions of the center portion of the second interconnection area A2 and the center portion of the second semiconductor chip 40, the second interconnection area A2 and the second semiconductor chip 40 may form an asymmetrical structure in the first direction. The center portions of the first semiconductor chip 30, the second semiconductor chip 40, the first interconnection area A1, and the second interconnection area A2 may be a portion disposed between edges thereof. For example, the center portion of the second semiconductor chip 40 may be equally spaced between the first edge 40a and the second edge 40b and between the third edge 40c and the fourth edge 40d, and the center portion of the second interconnection area A2 may be equally spaced between the first edge A31 and the fourth edge A34 and between the second edge A32 and the third edge A33. It should be understood that embodiments are not limited thereto. For example, by adjusting the relative positions of the center portion of the first interconnection area A1 and the center portion of the first semiconductor chip 30, the first interconnection area A1 and the first semiconductor chip 30 may form an asymmetrical structure in the first direction. Various other modifications are possible.

In an embodiment, a ratio (D/L0) of the separation distance D between the first semiconductor chip 30 and the second semiconductor chip 40 to the interconnection interval LO between the first interconnection area A1 and the second interconnection area A2 may be about 0.5 or more. For example, the ratio (D/L0) may be between about 0.8 to 0.95.

In an embodiment, the separation distance D between the first semiconductor chip 30 and the second semiconductor chip 40 may be larger than the first distance L1. For example, a ratio (D/L1) of the separation distance D to the first distance L1 may be between about 1.5 to 10, and more particularly between about 2 to 6). The separation distance D between the first semiconductor chip 30 and the second semiconductor chip 40 may be larger than each of the third distance L3, the fourth distance L4, and the fifth distance L5. The separation distance D between the first semiconductor chip 30 and the second semiconductor chip 40 may be the same as or larger than the second distance L2.

In an embodiment, in a plan view, the separation distance D between the first semiconductor chip 30 and the second semiconductor chip 40 may be larger than an interval (e.g., a minimum interval) between the first semiconductor chip 30 and/or the second semiconductor chip 40 and an edge of the connection substrate 20 adjacent thereto, or an interval (e.g., a minimum interval) between neighboring second semiconductor chips 40.

In an embodiment, separation distances between edges of different components may be variously arranged. For example, the separation distance D may be larger than a first interval D1 between a first edge (an upper edge of FIG. 5) of the first semiconductor chip 30 and a first edge (an upper edge of FIG. 5) of the connection substrate 20 in the second direction. The separation distance D may be larger than a second interval D2 between a second edge (a lower edge of FIG. 5) of the first semiconductor chip 30 and a second edge (a lower edge of FIG. 5) of the connection substrate 20 in the second direction. For example, the separation distance D may be larger than a third interval D3 between a third edge (a left edge of FIG. 5) of the connection substrate 20 and a third edge (a left edge of FIG. 5) of the second semiconductor chip 40 adjacent thereto in the first direction. For example, the separation distance D may be larger than a fourth interval D4 between a fourth edge (a right edge of FIG. 5) of the connection substrate 20 and a fourth edge (a right edge of FIG. 5) of the second semiconductor chip 40 adjacent thereto in the first direction. For example, the separation distance D may be larger than a fifth interval D5 between a fifth edge (an upper edge of FIG. 5) of the connection substrate 20 and a fifth edge of the second semiconductor chip 40 adjacent thereto in the second direction. For example, the separation distance D may be larger than a sixth interval D6 between a sixth edge (a lower edge of FIG. 5) of the connection substrate 20 and a sixth edge of the second semiconductor chip 40 adjacent thereto in the second direction. In an embodiment, the separation distance D may be larger than a seventh interval D7 between the plurality of second semiconductor chips 40 in the second direction.

In this instance, at least two of the first to seventh intervals D1, D2, D3, D4, D5, D6, and D7 may be substantially the same. For example, the third interval D3 and the fourth interval D4 may be substantially the same. This may be in consideration of a process margin, a stability, or the like; embodiments are not limited thereto.

According to an embodiment, the separation distance D between the first semiconductor chip 30 and the second semiconductor chip 40 may be sufficiently secured. It should be understood that embodiments are not limited thereto. For example, the ratio (D/L0) of the separation distance D to the interconnection interval L0 may be smaller than about 0.5 or larger than about 0.95. In some embodiments, the separation distance D may be smaller than the second distance L2. In some embodiments, the ratio (D/L1) of the separation distance D to the first distance L1 may be smaller than about 1.5 or larger than about 10. In some embodiments, the separation distance D may be the same or smaller than at least one of the first to seventh intervals D1, D2, D3, D4, D5, D6, or D7.

According to an embodiment, by adjusting a relative position between the first interconnection area A1 or the second interconnection area A2 and the first semiconductor chip 30 or the second semiconductor chip 40, the interconnection interval L0 between the first interconnection area A1 and the second interconnection area A2 may be small and the separation distance D the first semiconductor chips 30 and the second semiconductor chip 40 may be increased. For example, by adjusting the relative position between the second interconnection area A2 and the second semiconductor chip 40 in the first direction, the interconnection interval L0 between the first interconnection area A1 and the second interconnection area A2 may be small, and the separation distance D between the first semiconductor chip 30 and the second semiconductor chip 40 may be increased. Accordingly, a heat transfer (e.g., a coupling heat transfer) between the plurality of semiconductor chips 30 and 40 may be effectively suppressed or prevented. For example, heat generated by the first semiconductor chip 30 may be localized to the first semiconductor chip 30. As a result, a heat dissipation property of the first semiconductor package 100 may be improved. For example, heat generated by the first semiconductor chip 30 and conducted to the second semiconductor chip 40 may be effectively suppressed or prevented. Therefore, performance of the first semiconductor package 100 may be improved by reducing power for heat dissipation and reducing an operating temperature of the first semiconductor package 100. For example, performance of the second semiconductor chip 40 may be effectively secured. This may be more effective when the power of the first semiconductor chip 30 or a logic chip is gradually increased to improve the performance of the first semiconductor package 100.

On the other hand, in the conventional art, a separation distance between a plurality of semiconductor chips is small and heat is readily transferred between the semiconductor chips such that an operating temperature may be increased, and performance may be deteriorated. Further, additional power may be required to drive a cooling member to reduce the operating temperature.

In FIG. 1 to FIG. 5, an example in which the first semiconductor chip 30 is disposed between multiple second semiconductor chips 40. For example, as illustrated, two second semiconductor chips 40 may be disposed on a first side of the first semiconductor chip 30 and two second semiconductor chips 40 may be disposed on a second side of the first semiconductor chip 30, where the first side is opposite to the second side. An example in which the size of the second semiconductor chip 40 is smaller than the size of the first semiconductor chip 30 is illustrated. It should be understood that embodiments are not limited thereto. One or more second semiconductor chips 40 may be disposed on opposite sides of the first semiconductor chip 30. In some embodiments, a number of the second semiconductor chip(s) 40 at a first side of the first semiconductor chip 30 may be different from a number of the second semiconductor chip(s) 40 at a second side of the first semiconductor chip 30. In some embodiments, a size of the second semiconductor chip 40 may be the same as or larger than a size of the first semiconductor chip 30. As such, embodiments are not limited to a number, an arrangement, or a size of the first semiconductor chip 30 and/or the second semiconductor chip 40, and various other modifications are possible.

In the above, an example in which the first semiconductor chip 30 is or includes the logic chip and the second semiconductor chip 40 is or includes the memory chip is described. Embodiments are not limited thereto, a structure, a function, or the like of the first semiconductor chip 30 or the second semiconductor chip 40 may be variously modified.

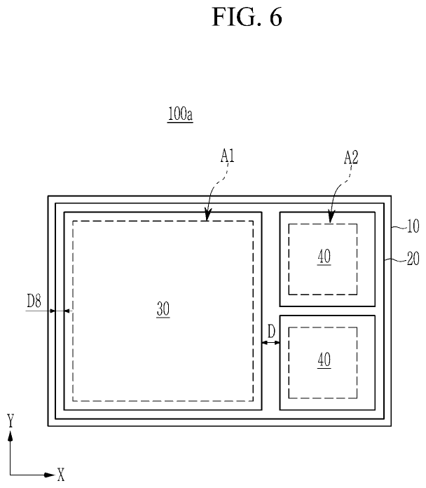

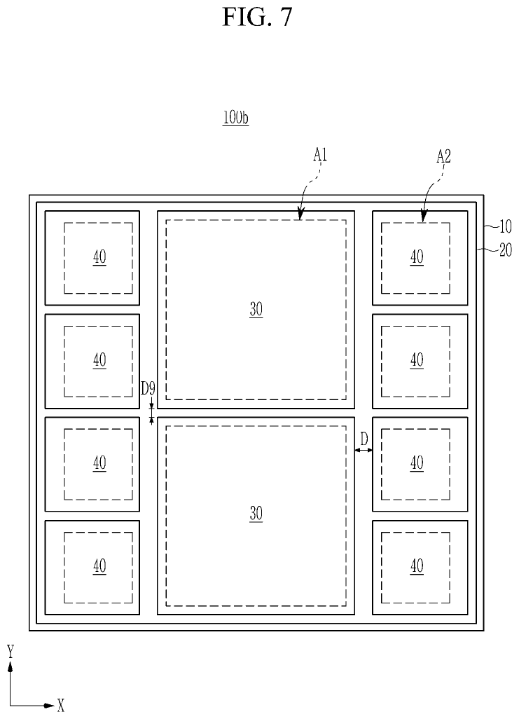

Hereinafter, a memory chip and a semiconductor package including the same according to embodiments will be described in detail with reference to FIG. 6 and FIG. 7. To the extent that an element may not be described in detail below, it may be understood that the element is at least similar to a corresponding element that has been described elsewhere within the present disclosure.

FIG. 6 is a plan view schematically illustrating a semiconductor package according to an embodiment. To provide concise illustrations and a clear understanding, a molding portion 50 (refer to FIG. 2) is not illustrated in FIG. 6.

Referring to FIG. 6, in a second semiconductor package 100a according to an embodiment, a first semiconductor chip 30 may be a first side (a left side of FIG. 6) and a second semiconductor chip 40 may be at a second side (a right side of FIG. 6) in a first direction (an X-axis direction in the drawing).

In an embodiment, in a plan view, a separation distance D between the first semiconductor chip 30 and the second semiconductor chip 40 may be larger than an interval (e.g., a shortest interval) between the first semiconductor chip 30 and/or the second semiconductor chip 40 and an edge of the connection substrate 20 adjacent thereto or an interval (e.g., a shortest interval) between neighboring second semiconductor chips 40.

In an embodiment, separation distances between edges of different components may be variously arranged. For example, the separation distance D may be larger than an eighth interval D8 between an eighth edge (a left edge of FIG. 6) of the first semiconductor chip 30 and an eighth edge (a left edge of FIG. 6) of the connection substrate 20 in the first direction. The separation distance D may be larger than a first interval D1 (refer to FIG. 5), a second interval D2 (refer to FIG. 5), a fourth interval D4 (refer to FIG. 5), a fifth interval D5 (refer to FIG. 5), a sixth interval D6 (refer to FIG. 5), and/or a seventh interval D7 (refer to FIG. 5). This has been described in detail with reference to FIG. 5, and thus, a detailed description may be omitted hereinafter.

In this instance, at least two of the first, second, fourth to eighth intervals D1, D2, D4, D5, D6, D7, and D8 may be substantially the same. For example, the eighth interval D8 and the fourth interval D4 may be substantially the same. This may be in consideration of a process margin, a stability, or the like; it should be understood that embodiments are not limited thereto.

According to an embodiment, the separation distance D between the first semiconductor chip 30 and the second semiconductor chip 40 may be sufficiently secured. It should be understood that embodiments are not limited thereto. For example, the separation distance D may be the same as or smaller than at least one of the first, second, fourth to eighth intervals D1, D2, D4, D5, D6, D7, or D8.

In FIG. 6, an example in which a size of the second semiconductor chip 40 is smaller than a size of the second semiconductor chip 30 and two second semiconductor chips 40 are at a same side of the first semiconductor chip 30 is illustrated. It should be understood that embodiments are not limited thereto. In some embodiments, one or more second semiconductor chips 40 may be provided at one or more sides of the first semiconductor chip 30. In some embodiments, a size of the second semiconductor chip 40 may be the same as or larger than a size of the first semiconductor chip 30. As such, embodiments are not limited to a number, an arrangement, or a size of the first semiconductor chip 30 and/or the second semiconductor chip 40, and various modifications are possible.

FIG. 7 is a plan view schematically illustrating a semiconductor package according to an embodiment. To provide concise illustrations and a clear understanding, a molding portion 50 (refer to FIG. 2) is not illustrated in FIG. 7.

Referring to FIG. 7, in a third semiconductor package 100b according to an embodiment, a plurality of first semiconductor chips 30 may be disposed in a second direction (a Y-axis direction in the drawing). The second semiconductor chip 40 may be at a side of the first semiconductor chip 30 in the first direction. The second semiconductor chip 40 may be disposed at a first side or a second side of the first semiconductor chip 30. Different second semiconductor chips 40 may be disposed at different sides of the first semiconductor chip 30. Different second semiconductor chips 40 may be disposed at different sides of different first semiconductor chips 30.

In an embodiment, in a plan view, a separation distance D between the first semiconductor chip 30 and the second semiconductor chip 40 may be larger than an interval (e.g., a minimum interval) between the first semiconductor chip 30 and/or the second semiconductor chip 40 and an edge of the connection substrate 20 adjacent thereto, or an interval (e.g., a minimum interval) between neighboring second semiconductor chips 40.

For example, the separation distance D may be larger than a ninth interval D9 between the first semiconductor chips 30 neighboring each other in the second direction. The separation distance D may be larger than first to eighth intervals D1, D2, D3, D4, D5, D6, D7, D8 (refer to FIG. 5 or FIG. 6). In this instance, at least two of the first to ninth intervals D1, D2, D3, D4, D5, D6, D7, D8, and D9 may be substantially the same.

According to an embodiment, the separation distance D between the first semiconductor chip 30 and the second semiconductor chip 40 may be sufficiently secured. It should be understood that embodiments are not limited thereto. For example, the separation distance D may be the same as or smaller than at least one of the first to ninth intervals D1, D2, D3, D4, D5, D6, D7, D8, or D9.

In FIG. 7, an example in which the first semiconductor chip 30 and the plurality of semiconductor chips 40 shown in FIG. 1 are provided in plural in the second direction is illustrated. It should be understood that embodiments are not limited thereto. The first semiconductor chip 30 and the plurality of semiconductor chips 40 as a unit and shown in FIG. 6 may be provided in plural in the second direction. Modified embodiments related to FIG. 1 and modified embodiments related to FIG. 6 may be applied to the first semiconductor chip 30 and the plurality of semiconductor chips 40 of FIG. 7.

While embodiments of the present disclosure have been described in connection with what is presently considered to be practical aspects, it is to be understood that the disclosure is not necessarily limited thereto, but on the contrary, are intended to cover various modifications and equivalent arrangements included within the spirit and scope of the present disclosure.

What is claimed is:

1. A semiconductor package, comprising:
a connection substrate;
a first semiconductor chip on the connection substrate and including a first interconnection area facing the connection substrate; and
a second semiconductor chip on the connection substrate and including a second interconnection area facing the connection substrate,
wherein the second semiconductor chip includes a first edge adjacent to the first semiconductor chip and a second edge opposite to the first edge in a first direction, and
a first distance between the second interconnection area and the first edge in the first direction is different from a second distance between the second interconnection area and the second edge in the first direction.

2. The semiconductor package of claim 1, wherein:
the first distance is smaller than the second distance.

3. The semiconductor package of claim 1, wherein:
a ratio of the second distance to the first distance is between about 1.5 to 10.

4. The semiconductor package of claim 1, further includes at least one of an asymmetrical structure, in the first direction, including the second interconnection area and the second semiconductor chip, or
the second semiconductor chip shifted in a direction away from the first semiconductor chip in the first direction, relative to a position of the second interconnection area.

5. The semiconductor package of claim 1, wherein:
the second semiconductor chip includes a plurality of connection pads in the second interconnection area,
the semiconductor package further comprises a plurality of interconnection members between the plurality of connection pads and the connection substrate, wherein the plurality of interconnection members connecting the plurality of connection pads and the connection substrate, and
the second semiconductor chip is shifted in a direction away from the first semiconductor chip in the first direction, relative to a position of the plurality of connection pads or the plurality of interconnection members.

6. The semiconductor package of claim 1, wherein:
the second semiconductor chip includes a plurality of semiconductor dies connected through a plurality of penetration electrodes, and
the second interconnection area and a penetration interconnection area where the plurality of penetration electrodes are positioned have an asymmetrical structure in the first direction.

7. The semiconductor package of claim 1, wherein:
the second interconnection area and the second semiconductor chip form a symmetrical structure in a second direction crossing the first direction.

8. The semiconductor package of claim 1, wherein:
the second semiconductor chip includes a third edge crossing the first edge and the second edge, and
a third distance between the second interconnection area and the third edge in a second direction crossing the first direction is larger than the first distance and is smaller than the second distance.

9. The semiconductor package of claim 1, wherein:
a separation distance between the first semiconductor chip and the second semiconductor chip is larger than the first distance.

10. The semiconductor package of claim 1, wherein:
a ratio of a separation distance between the first semiconductor chip and the second semiconductor chip to an interconnection interval between the first interconnection area and the second interconnection area is about 0.5 or more.

11. The semiconductor package of claim 1, wherein:
a separation distance between the first semiconductor chip and the second semiconductor chip is larger than a distance between the first interconnection area and an edge of the first semiconductor chip.

12. The semiconductor package of claim 1, wherein, in a plan view:
a separation distance between the first semiconductor chip and the second semiconductor chip is larger than an interval between an edge of the first semiconductor chip and an edge of the connection substrate or an interval between an edge of the second semiconductor chip and an edge of the connection substrate.

13. The semiconductor package of claim 1, wherein:
the first semiconductor chip includes a logic chip, and
the second semiconductor chip includes a memory chip.

14. The semiconductor package of claim 1, wherein:
the first interconnection area and the first semiconductor chip have a symmetrical structure in the first direction.

15. A memory chip, comprising:
a plurality of semiconductor dies; and
a plurality of connection pads at a surface of the plurality of semiconductor dies,
wherein the memory chip includes a first edge at a first side and a second edge at a second side opposite to the first side in a first direction, and
a first distance between the first edge and a first pad of the plurality of connection pads adjacent to the first edge in the first direction is smaller than a second distance between the second edge and a second pad of the plurality of connection pads adjacent to the second edge in the first direction.

16. The memory chip of claim 15, wherein:
the plurality of semiconductor dies are connected through a plurality of penetration electrodes, and
an interconnection area where the plurality of connection pads are positioned and a penetration interconnection area where the plurality of penetration electrodes are positioned forms an asymmetrical structure in the first direction.

17. The memory chip of claim 15, further including a third edge crossing the first edge and the second edge, wherein
a third distance between the third edge and a third pad of the plurality of connection pads adjacent to the third edge in a second direction crossing the first direction is larger than the first distance and is smaller than the second distance.

18. The memory chip of claim 15, wherein:
the memory chip comprises a high bandwidth memory chip mounted on a connection substrate adjacent to a semiconductor chip.

19. A semiconductor package, comprising:
an interposer;
a logic chip on the interposer and including a first interconnection area configured to be connected to the interposer; and
a memory chip on the interposer and including a second interconnection area configured to be connected to the interposer,
wherein the memory chip includes a first edge adjacent to the logic chip and a second edge opposite to the first edge in a first direction, and
a first distance between the second interconnection area and the first edge in the first direction is different from a second distance between the second interconnection area and the second edge in the first direction.

20. The semiconductor package of claim 19, wherein:
a center portion of the memory chip and a center portion of the second interconnection area are offset from each other in the first direction, and
the first interconnection area and the logic chip form a symmetrical structure in the first direction in which a center portion of the logic chip and a center portion of the first interconnection area are aligned to each other.
